(19) United States
(12) Patent Application Publication
(10) Pub. No.: US 2025/0210360 A1
(43) Pub. Date: Jun. 26, 2025

(54) METHOD FOR FORMING HYDROPHOBIC ZONES ON A SUBSTRATE

(71) Applicant: Commissariat a I'Énergie Atomique et aux Énergies Alternatives, Paris (FR)

(72) Inventors: Franck Fournel, Grenoble (FR); Pierre Montmeat, Grenoble (FR); Thierry Enot, Grenoble (FR)

(73) Assignee: Commissariat a I'Énergie Atomique et aux Énergies Alternatives, Paris (FR)

(21) Appl. No.: 18/999,091

(22) Filed: Dec. 23, 2024

(30) Foreign Application Priority Data
Dec. 26, 2023 (FR) 2315316

(51) Int. Cl. H01L 21/306

(52) U.S. Cl. CPC H01L 21/30604

(57) ABSTRACT

A method of forming hydrophobic zones including the following steps: providing a structure comprising a substrate of interest bonded to a temporary substrate, the temporary substrate including a base substrate locally covered with pads and with raised elements having a height lower than the height of the pads, the raised elements surrounding the pads and extending to the edge of the temporary substrate, interstices separating the substrate of interest from the raised elements,bringing into contact the structure with a solution comprising a hydrophobic compound or an etchant, whereby the solution seeps into the interstices and hydrophobic zones are formed on the substrate of interest opposite the raised elements.

### CROSS REFERENCE TO RELATED APPLICATIONS

This application claims priority to French application number 2315316, filed Dec. 26, 2023, the contents of which is incorporated by reference in its entirety.

### TECHNICAL FIELD

The present disclosure generally concerns the field of microelectronics, and more particularly substrates for chip-to-wafer type bonding.

### PRIOR ART

In the context of chip-to-wafer bonding, chips have to be positioned on a wafer in predefined zones. To facilitate the positioning of chips, it is possible to create, on the wafers, hydrophilic zones surrounded by hydrophobic zones. The chips, conveyed with a liquid (typically water), will then spontaneously position on the hydrophilic zones.

To form hydrophobic zones around hydrophilic zones on a wafer, it is common practice to bond a wafer having a hydrophilic surface to a temporary wafer covered with pads. The pads protect the zones on which the chips will be subsequently positioned. The structure thus obtained is then brought into contact, by immersion for example, with a liquid capable of making the wafer surface hydrophobic. The aim is to propagate the liquid around the pads to make the surface around the pads hydrophobic. The portion positioned under the pads is not in contact with the liquid and remains hydrophilic.

However, in certain cases, this penetration is relatively slow and air bubbles may get trapped between the two wafers, which prevents the propagation of the liquid and results in zones which remain hydrophilic instead of becoming hydrophobic, which is particularly inconvenient for the chip positioning.

### SUMMARY OF THE INVENTION

There exists a need to have a method enabling to reliably create hydrophobic zones around hydrophilic zones.

This aim is achieved by a method of forming hydrophobic zones on a substrate of interest, the method comprising the following steps:
providing the substrate of interest comprising a first hydrophilic surface and a temporary substrate comprising a base substrate locally covered with pads and with raised elements having a height lower than the height of the pads, a first portion of the raised elements being peripheral elements surrounding the pads and a second portion of the raised elements being fluidic connection elements extending from the peripheral elements to the edge of the temporary substrate,
bonding the pads of the temporary substrate to the first hydrophilic surface of the substrate of interest, whereby the substrate of interest is separated from the raised elements by interstices,
bringing into contact the substrate of interest with a solution comprising a hydrophobic compound or an etchant, whereby the solution seeps into the interstices and hydrophobic zones are formed on the substrate of interest opposite the raised elements.

Advantageously, the raised elements have a height amounting to less than 50%, and preferably less than 10%, of the height of the pads.

Advantageously, the interstices have a height in the range from 0.1 to 10 μm, preferably from 1 to 5 μm.

Advantageously, the pads have a height in the range from 10 to 100 μm.

Advantageously, the fluidic connection elements form a periphery on the base substrate.

Advantageously, the fluidic connection elements are positioned discontinuously along the periphery of the base substrate, so as to form vents between the fluidic connection elements.

Advantageously, the raised elements have a width in the range from 10 μm to 2.5 mm.

Advantageously, the pads have a surface area in the range from 0.25 to 400 mm².

Advantageously, the substrate comprises zones of higher topographies and/or of metal interconnection, having the pads bonded thereto.

Advantageously, only one edge of the substrate of interest is brought into contact with the solution, at the location of a fluidic connection element.

This aim is also achieved by a substrate having a first surface comprising hydrophilic zones surrounded by hydrophobic zones, preferably having a width in the range from 10 μm to 2.5 mm, hydrophobic lines coupling the hydrophobic zones to the edge of the substrate.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, FIG. 1C, FIG. 1D, and FIG. 1E schematically show different steps of a method of manufacturing a substrate of interest covered by hydrophobic zones;

FIG. 2 and FIG. 3 show, schematically and in top view, a substrate of interest according to different specific embodiments of the invention;

FIG. 4A, FIG. 4B, FIG. 4C, FIG. 4D, FIG. 4E, FIG. 4F, FIG. 4G, and FIG. 4H schematically show different steps of a method of manufacturing a temporary substrate according to a specific embodiment of the invention.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

Although the description particularly refers to substrates for chip-to-wafer type bonding, the method is particularly advantageous for all applications requiring to propagate a liquid around pads across a given width or at specific locations without necessarily wetting the entire free space between wafers.

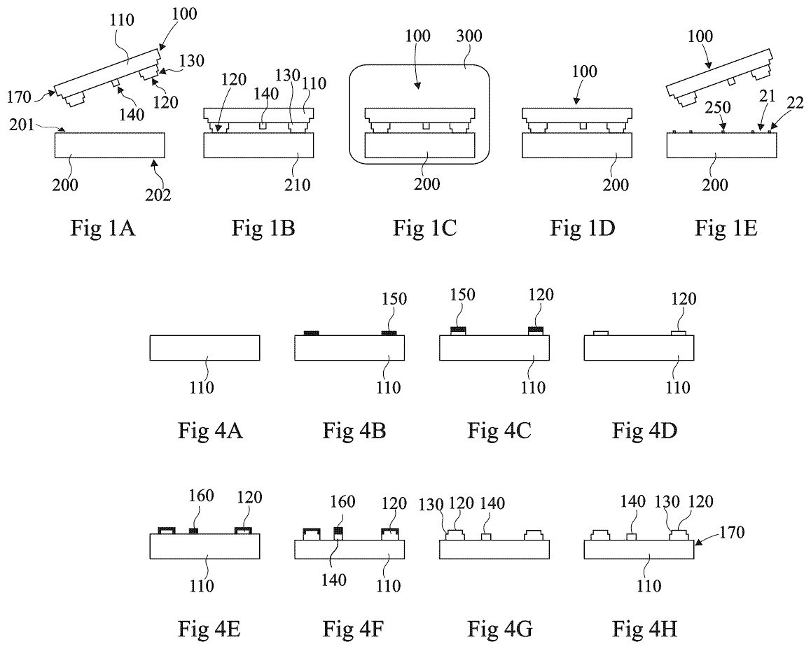

There will now be described in further detail the method of forming hydrophilic zones Z1 surrounded by hydrophobic zones Z2 on a substrate of interest 200 with reference to FIGS. 1A, 1B, 1C, 1D, and 1E.

The method comprises the following steps:
a) providing the substrate of interest 200 and a temporary substrate 100, the substrate of interest 200 having a first hydrophilic surface 201 and a second surface 202, the temporary substrate 100 comprising a base substrate 110 locally having, at its surface, pads 120 and raised elements 130, 140 having a height lower than the height of pads 120, a first part of the raised elements corresponding to so-called peripheral elements 130 surrounding pads 120, a second part of the raised elements corresponding to so-called fluidic connection elements 140 extending from peripheral elements 130 to the edge of temporary substrate 200, (FIG. 1A),
b) bonding temporary substrate 100 to the first surface 201 of the substrate of interest 200, and more particularly bonding the pads 120 of temporary substrate 100 to the first surface 201 of the substrate of interest 200, the substrate of interest 200 being separated from raised elements 130, 140 by interstices (FIG. 1B),
c) bringing the structure obtained at step b) into contact with a solution 300 comprising a compound enabling to make the surface 201 of the substrate of interest 200 hydrophobic, whereby solution 300 seeps into the interstices and hydrophobic zones Z2, Z3 are formed on the first surface 201 of the substrate of interest 200 facing raised elements 130, 140 (FIGS. 1C, 2, and 3),
d) preferably, cleaning the substrate (FIG. 1D),
e) separating temporary substrate 100 from the substrate of interest 200 (FIG. 1E).

Between the two substrates 100, 200, there are several different types of spacings (or gaps):
interstices (small gap zones) between the substrate of interest 200 and raised elements 130, 140,
spaces (large gap zones) between the substrate of interest 200 and the base substrate 110 of temporary substrate 100.

The interstices have a height amounting to less than 50% and, preferably, less than 10%, of the height of the large gap zones.

The interstices having a very small height as compared with the height of the spaces between the substrate of interest 200 and the base substrate 110 of temporary substrate 100, the wetting will preferably take place in the interstices (that is, between the two surfaces separated by the smallest spacing) because capillary forces will be strongest at this level.

Such a method enables to efficiently propagate the liquid between the pads 120 of two wafers bonded to each other.

With such a method, it is possible to obtain a partial wetting and to increase the wetting kinetics by adjusting the height of the interstices.

The substrate of interest 200 is preferably a wafer.

The substrate of interest 200 is, for example, a substrate made of semiconductor material (preferably Si, Ge, SiC, AsGa), of sapphire, or of silica.

The substrate of interest 200 provided at step a) may be a SOI (‘Silicon on Insulator’) substrate, that is, comprising a support substrate successively covered by a thin film of buried oxide and a silicon layer.

Alternatively, it may be a solid substrate made of a semiconductor material (silicon, for example) covered with a dielectric layer, in particular an oxide layer (silicon oxide, in particular).

The substrate of interest 200 has a first surface 201 and a second surface 202. The first surface 201 is a hydrophilic surface.

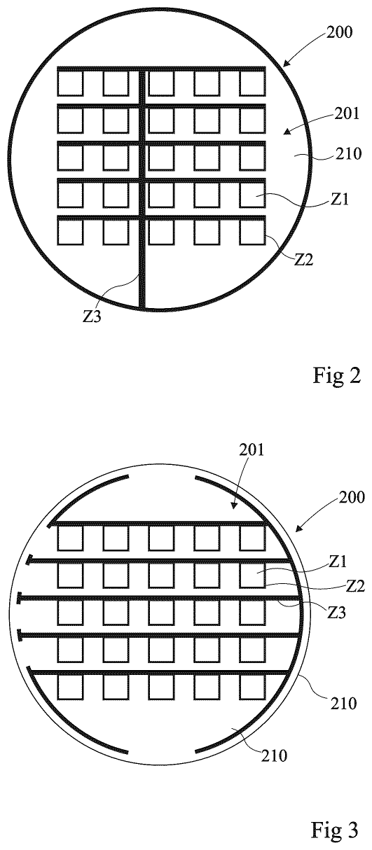

The first surface 201 comprises first zones Z1 which are desired to be kept hydrophilic and second zones Z2 surrounding the first zones which are desired to be made hydrophobic (FIGS. 2 and 3). The first zones Z1 will be protected by the pads 120 of temporary substrate 100 after the bonding of step b).

The first zones Z1 may be zones of higher topography and/or metal interconnection zones intended to be connected to chips. By high topography, there is meant that the first zones Z1 protrude by at least 100 nm and more particularly by 500 nm, or even 1 μm, from the substrate surface.

The first zones Z1 may be arranged regularly or irregularly. They may be of same dimension or of different dimensions.

Temporary substrate 100 comprises base substrate 110, pads 120 (pillars or columns), and raised elements 130, 140.

The base of pads 120 may have different shapes. It may be square, rectangular, or even circular.

Solution 300 being brought to the zones to be made hydrophobic by means of the interstices, pads 120 may be spaced apart by small distances or by larger distances. The spacing of pads 120 will be selected according to the desired application. Pads 120 are for example spaced apart by more than 10 μm, or by more than 50 μm or less. They may also be spaced apart by a few millimeters.

Raised elements 130, 140 have a height lower than the height of pads 120. The different raised elements 130, 140 may have identical or different heights. Preferably, the heights are identical or substantially identical.

Raised elements 130, 140 preferably have a width in the range from 10 μm to 2.5 mm.

A first part of the raised elements corresponds to so-called peripheral elements 130 positioned around the pads 120, forming the peripheral part of pads 120. During the bonding, the portion of the substrate of interest 200 facing the peripheral elements 130 corresponds to the zones Z2 which are desired to be made hydrophobic.

A second part of the raised elements corresponds to so-called fluidic connection elements 140, enabling to couple the peripheral elements 130 positioned around pads 120 to the edge of the substrate. During the bonding, the interstices formed opposite these elements form flow paths or channels for the solution, which emerge onto the edge of the substrate of interest 200.

Each peripheral element 130 is coupled to the edge of the substrate by means of a fluidic connection element 140. A fluidic connection element 140 may enable to couple a plurality of peripheral elements 130 to the edge of the substrate.

Fluidic connection elements 140 are, for example, arranged in line at the center of base substrate 110.

The raised elements may further cover part or all of the periphery of base substrate 110.

According to a first variant, the raised elements cover the entire periphery of base substrate 110.

According to another variant, the raised elements cover only part of the periphery of base substrate 110. This enables to create one or a plurality of vents to enable, when present, the air expelled by the incoming of solution 300 to escape.

Base 110, pads 120, and raised elements 130 may be made of different materials. Preferably, they are made of a same material. It may be a metal or a semiconductor material, for example. Preferably, it is made of silicon.

Temporary substrate 100 is preferably obtained from a solid substrate.

In particular, temporary substrate 100 may be manufactured with photolithography steps. As an illustration, as shown in FIGS. 4A to 4H, the substrate may be manufactured according to the following steps:
providing a substrate 110 (FIG. 4A),
depositing locally resin 150 on substrate 110 (FIG. 4B),
etching the portions of the substrate not covered by resin 150 to delimit the upper portion of pads 120 (FIG. 4C),
removing resin 150 (FIG. 4D),
depositing additional resin 160, on the one hand, on the top and on the sides of the upper portion of pads 120, to be able to complete the forming of pads 120 and to be able to form the peripheral elements 130 surrounding the pads, and on the other hand, locally on substrate 110 in line with the future zones of fluidic connection elements 140 (FIG. 4E),
etching substrate 110 to form pads 120 and raised elements 130, 140 (FIG. 4F),
removing additional resin 160 (FIG. 4G),
optionally, trimming substrate 110 (FIG. 4H).

The trimming of the edge of wafer 110 enables to avoid any edge contact between temporary substrate 100 and the substrate of interest 200, especially if pad 120 is not very thick.

The trimming may be carried out, for example, by photolithography/etching or also by mechanical trimming by means of a diamond saw. The width of the trimming, in the substrate plane, is for example in the range from 1 to 5 mm and/or its depth, in a plane perpendicular to that of the substrate, is for example in the range from 100 to 250 μm.

Prior to step b), it is possible to carry out one or a plurality of pre-treatments on the surface of temporary substrate 100 and/or on the surface of the substrate of interest 200 in order to make them compatible with a direct bonding.

The pre-treatment may be selected from among the following pre-treatments: thermal anneal, plasma, polishing, and wet cleaning.

As an example, it is possible to form an oxide layer on the surface of temporary substrate 100 and/or to perform a polishing step on temporary substrate 100 and/or on the substrate of interest 200 to obtain a roughness compatible with a direct bonding (typically a roughness lower than 0.5 nm RMS). It is possible to implement processes which combine, for example, a plasma and an aqueous solution, in particular an oxygen plasma followed by a wet CARO cleaning (H₂SO₄, H₂O₂ in a 5:1 proportion) associated with SC1 (H₂O, NH₃, H₂O₂ in a 5:1:1 proportion).

In step b), temporary substrate 100 and the substrate of interest 200 are bonded.

The two substrates 100, 200 may be assembled by direct bonding. The use of marks on substrates 100, 200 may facilitate their alignment. A precision of approximately 100 nm can be achieved. It is also possible to align them, without using marks, by using the edges of the substrates as well as their notch. The precision is lower (+/−50 μm), but sufficient for certain applications.

The direct bonding may be performed at the atmospheric pressure (that is, 1,013.25 hPa) or in vacuum. The assembling does not necessarily need to be consolidated by a heat treatment. However, an anneal, at a temperature preferably lower than 200° C., may advantageously be carried out. It is possible to anneal at a higher temperature, but there is a risk of damaging the surfaces during the final separation between the two substrates 100 and 200.

During the bonding, the pads 120 of temporary substrate 100 are bonded to the first surface 201 of the substrate of interest 200, and more particularly to the first hydrophilic zones Z1 of substrate 200 to be protected during step c). The peripheral raised elements 130 around pads 120 are positioned opposite the second zones Z2 of substrate 100 which are desired to be made hydrophobic (FIGS. 2 and 3).

During the bonding, the height of the spaces between substrates 110, 200 (large gap zones) varies, for example, between 10 μm and 100 μm. The height of the large gap zones may be constant within a same assembly, but it may also slightly vary (typically by less than 10%).

The bonding results in the forming of interstices between the first surface 201 of the substrate of interest 200 and the raised elements 130, 140 of temporary substrate 100. The thickness (or height) of the interstices varies, for example, between 0.1 μm and 10 μm, preferably between 1 μm and 5 μm.

The height of the small gap zones is generally constant on the wafer to within 10%, but it may also intentionally vary. This may be advantageous to have wetting kinetics different according to the location on the wafer.

A first group of interstices is formed between peripheral raised elements 130 and the substrate of interest 200. The thickness (or height) of the interstices corresponds to the height difference between pads 120 and peripheral raised elements 130.

A second group of interstices is formed between the first surface 210 of substrate 200 and raised fluidic connection elements 140. These interstices thus form preferred paths for the liquid (step c)). The thickness of these interstices depends on the height difference between pads 120 and raised fluidic connection elements 140.

The structure comprises one or a plurality of paths for guiding solution 300 from the outside of the substrates to the zones Z2 to be made hydrophobic. The zones Z3 of the substrate of interest 200 positioned under these flow paths of solution 300 will also be hydrophobic at the end of the process (FIGS. 2 and 3).

During step c), the substrate of interest 200 is brought into contact with a solution 300. Solution 300 is a solution enabling to make the surface hydrophobic. It generally is a solution comprising hydrophobic compounds which locally bind to the surface of the substrate of interest 200 to make it locally hydrophobic. It is also possible to make the surface hydrophobic by performing an etching, in particular of a surface layer to expose an underlying hydrophobic material.

The substrate of interest 200 may be brought into contact with solution 300 by total or partial immersion, or also by insertion or injection of solution 300 into the interstices formed during the bonding. Preferably, only one edge of the substrate of interest is brought into contact with solution 300.

Solution 300 seeps into the interstices positioned under the raised fluidic connection elements 140 all the way to the zones Z2 positioned under the peripheral raised elements 130.

The penetration of the solution through narrow paths is made possible by capillary forces. As shown in FIGS. 2 and 3, when the solution is located at the edge of a path termination, capillary forces will spontaneously enable the solution to fill all the paths without it being necessary to fully immerse the assembly. A contamination of the two external surfaces of the assembly by the solution is thus avoided.

The trimming facilitates the entering of liquid at the edge of the bonded structures.

In a first variant, the surface of substrate 200 in contact with the solution becomes hydrophobic as a result of the forming of a hydrophobic layer 250 at the location of the interstices (FIG. 1E).

The selection of hydrophobic layer 250 will depend, in particular, on the substrate of interest 200.

The resulting hydrophobic layer 250 has, for example, a thickness in the range from 2 nm to 100 nm.

Hydrophobic layer 250 may be obtained from a polymer, a silyl (also called organo-silyl), or a silane.

The selected hydrophobic compound preferably comprises one or a plurality of halogen groups, in particular fluorine or chlorine groups. Preferably, the hydrophobic compound comprises a carbon chain of at least 5 carbon atoms.

The silane may be a chlorosilane such as octadecyltrichlorosilane (OTS=CH₃(—CH₂)₁₇—SiCl₃) marketed by Sigma Aldrich.

The polymers may be fluoropolymers such as for example the Novec™ 1720 EGC polymer marketed by 3M™, the Optool marketed by DAIKIN, and the Novec™ 2202 EGC polymer marketed by 3M™. The hydrophobic compound may be selected from among chlorosilanes such as perfluorodecyl trichlorosilane (FDTS=Cl₃Si(CH₂)₂(CF₂)₇CF₃) marketed by Sigma-Aldrich, perfluorodecyl dimethylchlorosilane (FDDMCS=CF₃(CF₂)₇(CH₂)₂(CH₃)₂SiCl) marketed by Sigma-Aldrich.

As a variant, the surface of substrate 200 in contact with the solution may become hydrophobic by selective local etching of the surface layer of substrate 200, locally exposing a hydrophobic material of substrate 200.

For example, if the surface of substrate 200 is made of silicon, it is possible to make it hydrophobic by etching the native oxide layer present on the silicon surface with hydrofluoric acid (HF), for example with a solution containing 1% of HF.

After step c), a step d) of cleaning by means of a rinsing and, optionally, a drying step may be carried out. The drying may be carried out by centrifugation.

An anneal may enable to dry and/or stabilize hydrophobic layer 250.

During step e), temporary substrate 100 is separated from the substrate of interest 200. The assembly may be disassembled, for example by inserting a wedge between the two substrates 100, 200.

Temporary substrate 100 may be used in a new bonding/etch cycle. A cleaning is advantageously carried out between each use.

For example, it is possible to recycle it by implementing an oxygen plasma treatment followed by a wet cleaning.

Alternatively, since the bases of the pads 120 of temporary substrate 100 have not been exposed to the hydrophobic compound, they are still compatible with a direct bonding. Temporary substrate 100 may thus be directly reused.

At the end of the process, a substrate 200 having a first surface 201 comprising hydrophilic zones Z1 surrounded by hydrophobic zones Z2 (FIGS. 2 and 3) is obtained. Each hydrophilic zone Z1 is surrounded by a hydrophobic zone Z2.

The hydrophilic zones Z1 have, for example, a surface area in the range from 0.25 to 400 mm².

Hydrophobic zones Z2 are zones covered by a hydrophobic layer or zones of a hydrophobic material exposed by chemical etching.

Hydrophobic zones Z2 preferably have a width in the range from 10 μm to 2.5 mm. For a substrate on which the chips will be collectively bonded, the width of the hydrophobic zones is, for example, in the range from 400 μm to 2.5 mm. For a substrate on which the chips are individually bonded, the width of the hydrophobic zones is, for example, in the range from 10 μm to 2.5 mm, or even from 40 μm to 2.5 mm. Indeed, the individual placing of chips is generally much more precise than the collective placing.

Hydrophobic lines Z3 couple hydrophobic zones Z2 to the edge of substrate 200.

Various embodiments and variants have been described. Those skilled in the art will understand that certain features of these various embodiments and variants could be combined, and other variants will become apparent to those skilled in the art.

Finally, the practical implementation of the described embodiments and variants is within the abilities of those skilled in the art, based on the functional indications given hereabove.

### ILLUSTRATIVE AND NON-LIMITING EXAMPLES OF DIFFERENT EMBODIMENTS

### Example 1

On a silicon wafer having a 200-mm diameter, a photolithography/etching method enables to form 10×10 mm² pads with a 1-μm thickness, as well as linear raised elements, intended to form the interstices after bonding, enabling to convey/distribute the liquid to the zones to be made hydrophobic, and a raised ring-shaped element around the wafer.

A second photolithography/etching process enables to etch the entire surface and to form the large gap zones by etching, for example, 100 μm of silicon, while protecting the small gap zones as well as the pads of interest. The small gap areas have a 2.5-mm width. A trimming of a 3-mm width and a 200-μm depth of the wafer edge is performed with a diamond saw. This trimming is narrower than the raised ring-shaped element which thus remains after this step.

The surface of the temporary wafer is cleaned by an O₂ plasma followed by a cleaning which favors the wetting of the surface of the pads by the solution. The surface is thus also compatible with a direct bonding process. The cleaning may be, for example, carried out by wet CARO, SC1 process.

An SOI wafer of interest comprises a 205-nm silicon film and a 400-nm buried oxide layer. It undergoes a wet CARO/SC1 cleaning to make it compatible with a direct bonding process.

The substrate of interest and the temporary substrate are directly bonded.

Then, the assembly is immersed in a solution comprising the Novec™ 1720 EGC fluorinated compound marketed by 3M™. During this immersion, the solution will preferably penetrate through and along the small gap zones. An ultrasonic activation may be carried out. The assembly is then dried by centrifugation.

The temporary substrate is disassembled by inserting a wedge into the structure. A silicon wafer of interest comprising 10*10 mm² hydrophilic zones surrounded by hydrophobic zones of a width corresponding to the width of the small gap zones (2.5 mm) is obtained.

### Example 2

On a temporary silicon wafer with a 200-mm diameter, a photolithography/etching process enables to form 11×11 mm² pads having a 1-μm thickness, as well as raised elements (lines) enabling to convey the liquid from the edge of the wafer and to distribute it to the pads, and a raised ring-shaped element (ring) around the wafer.

A second photolithography/etching method enables etch the entire surface and to form the large gap zones by etching, for example, 100 μm of silicon, while protecting the small gap zones as well as the pads of interest. The width of the small gap zones is 2.5 mm. A trimming of a 3-mm width and a 200-μm depth of the edge of the temporary wafer with a diamond saw is performed.

The wafer surface is cleaned by O₂ plasma followed by a wet CARO, SC1 cleaning so as to make it hydrophilic and thus facilitate its wetting by the solution of interest. The temporary substrate is thus compatible with a direct bonding process.

An SOI wafer of interest comprises a 205-nm silicon film and a 400-nm buried oxide layer. This wafer undergoes a photolithography/etching process to form 10×10 mm² pads having a 1-μm thickness. Then, a wet CARO/SCI cleaning enables to make the surface of these pads compatible with a direct bonding process.

The two substrates are directly bonded by aligning the pads of the substrate of interest and of the temporary substrate. A solution comprising the Optool fluorinated compound marketed by DAIKIN is then locally delivered via a tube to the opening of a small gap zone. During this contact, the liquid will preferably penetrate through and along the small gap zones. Then, the assembly is dried by centrifugation. Advantageously, here, the back sides of the two substrates are not contaminated at all by the Optool liquid.

The temporary wafer is disassembled by inserting a wedge into the structure. A silicon wafer of interest comprising hydrophilic 10*10 mm² pads surrounded by hydrophobic zones having a width corresponds to the width of the small gap zones is obtained.

### Example 3

On a temporary silicon wafer having a 200-mm diameter, a photolithography/etching process enables to form, in a first step, the distribution lines rather than the pads. The lines enable to convey the liquid from the edge of the wafer and to distribute it to the pads with a 1-μm etching. A distribution ring around the wafer is also created.

A second photolithography/etching process enables to form 11×11 mm² pads with a 5-μm thickness.

A third photolithography/etching process enables to etch the entire surface and to form the large gap zones by etching, for example, 100 μm of silicon, while protecting the small gap zones as well as the pads of interest. A trimming of a 3-mm width and a 200-μm depth of the edge of the temporary substrate with a diamond saw is performed.

The surface of the temporary wafer is cleaned by an O₂ plasma followed by a wet CARO, SC1 cleaning to make it hydrophilic and thus facilitate the wetting of the substrate with the solution of interest. The substrate is thus compatible with a direct bonding process. The different etch heights enable to have different penetration speeds.

An SOI wafer of interest comprises a 205-nm silicon film and a 400-nm buried oxide layer. It undergoes a photolithography/etching method to form 10×10 mm² pads with a 1-μm thickness. Then, a wet CARO/SC1 cleaning enables to make compatible with a direct bonding process the surface of these pads.

The temporary substrate and the substrate of interest are directly bonded by aligning the pads of the two substrates. The assembling is only performed on a small portion of the assembly, while making sure that a small gap zone, at least, touches and often penetrates into the liquid. The liquid is a solution comprising the Optool fluorinated compound marketed by DAIKIN. The assembly is then dried by centrifugation. During this soaking, the liquid will preferably penetrate through and along the small gap zones. The liquid will move faster along the small gap zones which surround the pads of interest, which enables to rapidly redistribute the liquid around the pads, which are then more slowly surrounded. In this example, most of the surface of the back sides of the two substrates has not seen the liquid, and will thus not need to be cleaned.

The temporary wafer is disassembled by inserting a wedge into the structure. A silicon wafer of interest comprising 10*10 mm2 hydrophilic pads surrounded by hydrophobic zones of a width corresponding to the width of the small gap zones is obtained.

1. Method of forming hydrophobic zones on a substrate of interest, the method comprising the following steps:
providing the substrate of interest comprising a first hydrophilic surface and a temporary substrate comprising a base substrate locally covered with pads and with raised elements having a height lower than the height of the pads, a first part of the raised elements being peripheral elements surrounding the pads and a second part of the raised elements being fluidic connection elements extending from the peripheral elements to the edge of the temporary substrate,
bonding the pads of the temporary substrate to the first hydrophilic surface of the substrate of interest, whereby the substrate of interest is separated, on the one hand, from the raised elements by interstices and, on the other hand, from the base substrate of the temporary substrate by large gap zones,
bringing into contact the substrate of interest with a solution comprising a hydrophobic compound or an etchant, whereby the solution seeps into the interstices by capillary action and hydrophobic zones are formed on the substrate of interest opposite the raised elements,
separating the substrate of interest from the temporary substrate.

2. Method according to claim 1, wherein the interstices have a height amounting to less than 50% and, preferably, less than 10% of the height of the large gap zones.

3. Method according to claim 1, wherein the interstices have a height in the range from 0.1 to 10 μm, preferably from 1 to 5 μm.

4. Method according to claim 1, wherein the pads have a height in the range from 10 to 100 μm.

5. Method according to claim 1, wherein the fluidic connection elements form a periphery on the base substrate.

6. Method according to claim 1, wherein the fluidic connection elements are positioned discontinuously on the periphery of the base substrate, so as to form vents between the fluidic connection elements.

7. Method according to claim 1, wherein the raised elements have a width in the range from 10 μm to 2.5 mm.

8. Method according to claim 1, wherein the pads have a surface area in the range from 0.25 to 400 mm².

9. Method according to claim 1, wherein the substrate comprises zones of higher topographies and/or of metallic interconnection, having the pads bonded thereto.

10. Method according to claim 1, wherein only one edge of the substrate of interest is brought into contact with the solution, at the location of a fluidic connection element.

11. Substrate having a first surface comprising hydrophilic zones surrounded by hydrophobic zones, preferably having a width in the range from 10 μm to 2.5 mm, hydrophobic lines coupling the hydrophobic zones to the edge of the substrate.
